(19) United States
(12) Patent Application Publication
(10) Pub. No.: US 2021/0094439 A1
(43) Pub. Date: Apr. 1, 2021

(54) MANAGEMENT DEVICE AND ENERGY STORAGE APPARATUS

(71) Applicant: GS Yuasa International Ltd., Kyoto-shi (JP)

(72) Inventor: Tomohiro OKACHI, Kyoto-shi, Kyoto (JP)

(21) Appl. No.: 16/966,196

(22) PCT Filed: Jan. 15, 2019
(86) PCT No.: PCT/JP2019/000857

§ 371 Date: Jul. 30, 2020

(30) Foreign Application Priority Data
Jan. 30, 2018 (JP) 2018-013552

(51) Int. Cl. B60L 58/12; B60R 16/04; H01M 10/0525; H01M 10/42

(52) U.S. Cl. CPC B60L 58/12; B60R 16/04; H01M 2220/20; H01M 10/425; H01M 10/0525

(57) ABSTRACT

A management device for an energy storage device, the energy storage device being mounted in a vehicle and configured to supply power to a specific load that consumes power during parking. The management device includes: a circuit board equipped with a processing unit; a resistor that detects a current of the energy storage device; and a connecting member that electrically connects the resistor and the circuit board. The processing unit calculates SOC of the energy storage device based on the current detected by the resistor. The connecting member includes a signal line, and a shield layer that shields the signal line. One end of the signal line, is connected to the resistor by welding and joining, and the other end of the signal line, is connected to the circuit board by welding and joining.

### TECHNICAL FIELD

The present invention relates to a technique for improving the estimation accuracy of SOC.

### BACKGROUND ART

A battery mounted in a vehicle estimates SOC (state of charge) in order to manage a state of an energy storage device. The current integration method is one of the SOC estimation methods. In the current integration method, a measurement error of a current by a current measuring unit is accumulated. Therefore, in Patent Document 1 below, an energy storage device is periodically charged to full charge to correct an error in an estimated SOC value.

### PRIOR ART DOCUMENT

### Patent Document

Patent Document 1: JP-A-2008-262920

### SUMMARY OF THE INVENTION

### Problems to be Solved by the Invention

The battery may receive regenerative energy from the vehicle and may be used in a medium SOC range where SOC is about 60%. Therefore, in order to reach full charge, charging from the medium SOC range is necessary, and it is necessary to secure the charging time. The conditions for securing the charging time are limited when the vehicle is in a long running state, etc., so that there is a problem that the opportunity to correct the SOC estimation error is limited. Therefore, it is required to increase the estimation accuracy of SOC by increasing the measurement accuracy of a current and suppressing the accumulation of errors.

An object of the present invention is to improve the estimation accuracy of SOC by increasing measurement accuracy of a current.

### Means for Solving the Problems

Provided is a management device for an energy storage device, the energy storage device being mounted in a vehicle and configured to supply power to a specific load that consumes power during parking, the management device including: a circuit board equipped with a processing unit; a resistor that detects a current of the energy storage device; and a connecting member that electrically connects the resistor and the circuit board, in which the processing unit calculates SOC of the energy storage device based on the current detected by the resistor, in which the connecting member includes a signal line and a shield layer that shields the signal line, in which one end of the signal line is connected to the resistor by welding and joining, and in which the other end of the signal line is connected to the circuit board by welding and joining.

### Advantages of the Invention

In this configuration, the estimation accuracy of SOC can be improved by increasing measurement accuracy of a current.

### BRIEF DESCRIPTION OF THE DRAWINGS

FIG. 1 is a side view of an automobile applied to a first embodiment.

FIG. 2 is a perspective view of a battery.

FIG. 3 is an exploded perspective view of the battery.

FIG. 4 is a block diagram showing an electrical configuration of the battery.

FIG. 5 is a plan view of an inner lid.

FIG. 6 is a perspective view of a resistor.

FIG. 7 is a perspective view showing a connection structure of the resistor and a circuit board.

FIG. 8 is a plan view showing a connection structure of the resistor and the circuit board.

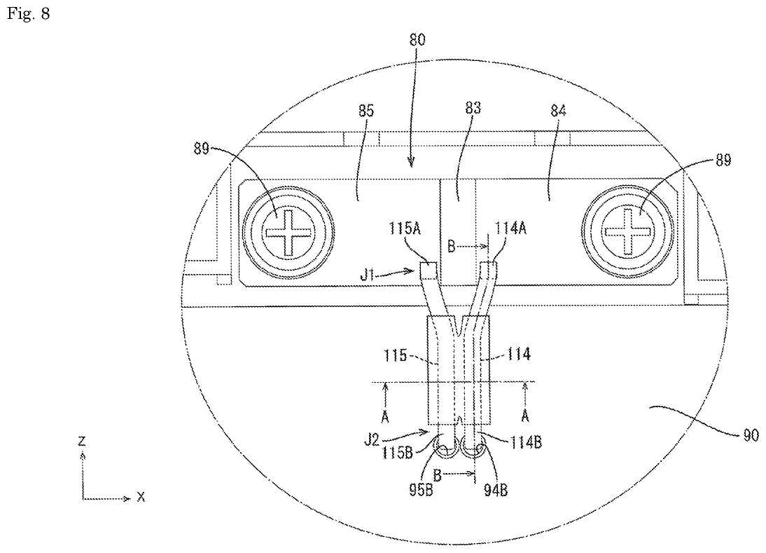

FIG. 9 is a cross-sectional view of a flexible wiring board.

FIG. 10 is a sectional view taken along line A-A of FIG. 8.

FIG. 11 is a sectional view taken along line B-B of FIG. 8.

FIG. 12 is a sectional view showing another connection structure of the resistor and the circuit board.

FIG. 13 is a sectional view showing another structure of the flexible wiring board.

### MODE FOR CARRYING OUT THE INVENTION

Provided is a management device for an energy storage device, the energy storage device being mounted in a vehicle and configured to supply power to a specific load that consumes power during parking. The management device includes: a circuit board equipped with a processing unit; a resistor that detects a current of the energy storage device; and a connecting member that electrically connects the resistor and the circuit board. The processing unit calculates SOC of the energy storage device based on the current detected by the resistor. The connecting member includes a signal line and a shield layer that shields the signal line. One end of the signal line is connected to the resistor by welding and joining, and the other end of the signal line is connected to the circuit board by welding and joining.

As a method of connecting the resistor and the circuit board, a method of connecting a terminal provided on the resistor to a connector of the circuit board is conceivable. In the case of connection using the connector, a spring of the terminal provided on the connector deteriorates over time and becomes weak. Then, there is a concern that the contact of the terminal becomes unstable, which may increase the contact resistance. As another method, a method of connecting the resistor and the circuit board with a signal wire and screwing them together is conceivable. Also in the case of screwing, similarly to the connector, there is a concern that the contact resistance may increase due to loosening of the screw due to deterioration over time. In this configuration, the signal line connecting between the resistor and the circuit board is welded and joined to the resistor and the circuit board. In the welding and joining, the resistance of a joining portion is small, and the deterioration over time is small. Therefore, the current can be accurately measured in the energy storage device in which a large current flows.

Since the signal line has a function of an antenna, the current may be measured to be larger than the actual current value by detecting external noise such as electromagnetic waves due to static electricity, substation equipment, or radio waves of a mobile phone. The measurement error caused by the external noise affects the measurement accuracy of the minute current. In this configuration, the shield layer provided in the connecting member shields external noise. Therefore, during parking, a minute current flowing from the energy storage device to the specific load of the vehicle can be accurately measured.

In this configuration, it is possible to highly accurately measure current from a minute current during parking to a large current at the time of an engine start. Therefore, an integration error of the current is small and the estimation accuracy of SOC can be improved.

The energy storage device may be a lithium ion secondary battery. The lithium ion secondary battery has a smaller internal resistance than other secondary batteries such as a lead-acid battery. Therefore, a large current may flow at the time of an engine start, as compared with the lead-acid battery. When the resistor is connected to the circuit board using the connector, the contact of the terminal becomes unstable due to deterioration over time and the contact resistance increases. Therefore, at the time of an engine start at which a large current flows, the current measurement error increases, and the estimation accuracy of SOC tends to decrease. By applying the present technology, it is possible to maintain a low resistance state at the joining portion between the resistor and the signal line, and at the joining portion between the circuit board and the signal line regardless of deterioration over time. Therefore, it is possible to solve the problem peculiar to the lithium ion secondary battery that the measurement accuracy of the current tends to decrease at the time of an engine start at which a large current flows.

The one end of the signal line may be joined to the resistor by laser welding or ultrasonic welding, and the other end of the signal line may be joined to the circuit board by soldering.

Soldering can be considered as a method of joining the signal line. Soldering has the merit that the equipment is inexpensive and the manufacturing cost can be suppressed. However, at the time of an engine start, a large current flows, and the resistor generates heat. Therefore, there is concern that the joining portion may be affected such that the solder may be melted or the like. In this configuration, the one end of the signal line is joined to the resistor by laser welding or ultrasonic welding. Since the melting point of copper, which is the base material of the signal line, is higher than that of solder, even if a large current flows through the resistor and heat is generated, the influence on the joining portion is small and the reliability is high. Since the other end of the signal line is joined to the circuit board by soldering, the manufacturing cost can be suppressed.

The connecting member may be a flexible wiring board including a substrate, the signal line, and the shield layer.

The flexible wiring board has a lower heat conductivity than a covered electric wire in which a core wire (signal wire) is covered with an insulating layer, and the heat of the resistor is hard to be transferred to the circuit board side. Therefore, since it is possible to suppress thermal shock (rapid temperature change) to the joining portion between the circuit board and the signal line, it is possible to suppress occurrence of solder cracks at the joining portion with the circuit board. Further, since the flexible wiring board is flexible, it is possible to reduce the concentration of stress on the joining portion between the circuit board and the signal line.

The resistor may be accommodated in a case that accommodates the energy storage device.

Since a large current flows at the time of an engine start and the energy storage device generates heat, in the case of the structure in which the resistor is accommodated in the same case as the energy storage device, heat is accumulated in the case, and the resistor is likely to reach a high temperature. In this configuration, by using the flexible wiring board having a low heat transfer rate, it is possible to suppress the transfer of heat from the resistor to the circuit board, so that it is possible to suppress temperature rise of the joining portion between the circuit board and the flexible wiring board. Therefore, deterioration of the measurement accuracy can be suppressed by suppressing deterioration over time due to heat.

### First Embodiment

### 1. Description of Battery

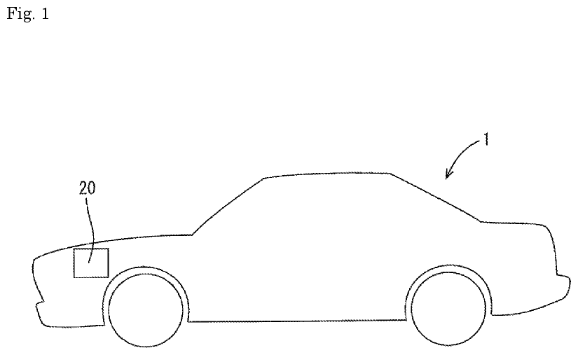

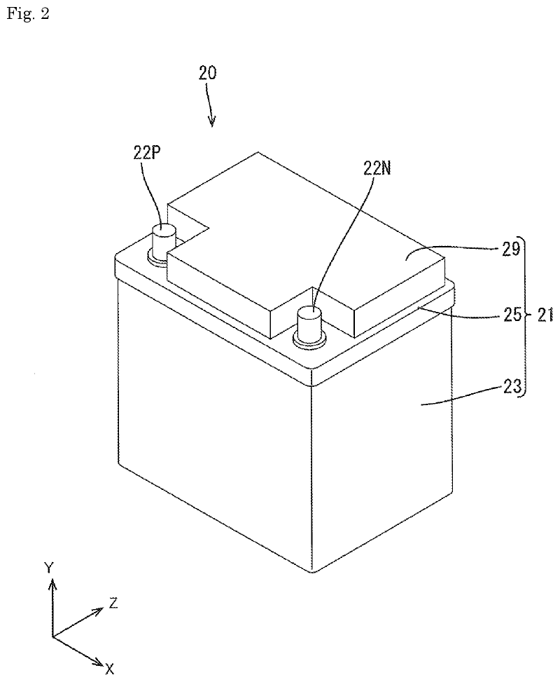

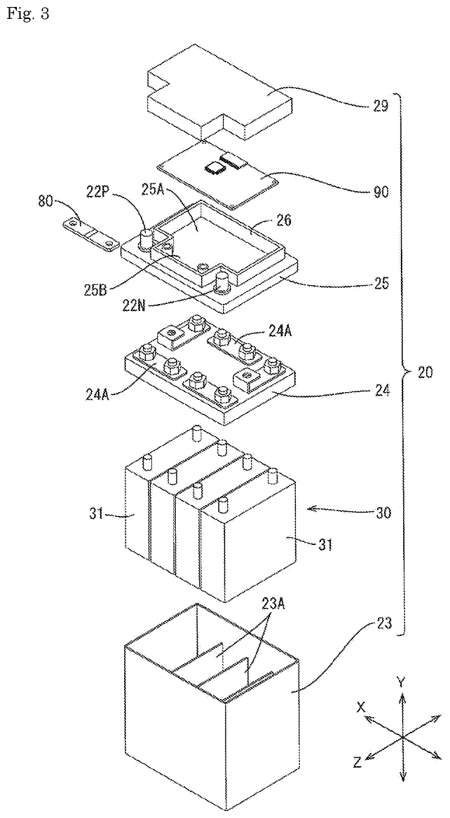

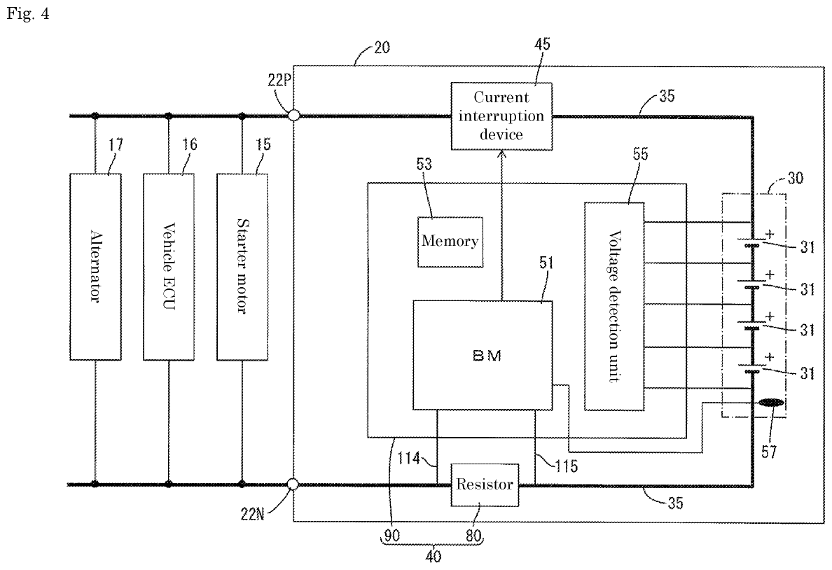

FIG. 1 is a side view of an automobile, FIG. 2 is a perspective view of a battery, FIG. 3 is an exploded perspective view of the battery, and FIG. 4 is a block diagram showing an electric configuration of the battery. In FIG. 1, only an automobile 1 and a battery 20 are shown, and other components constituting the automobile are omitted.

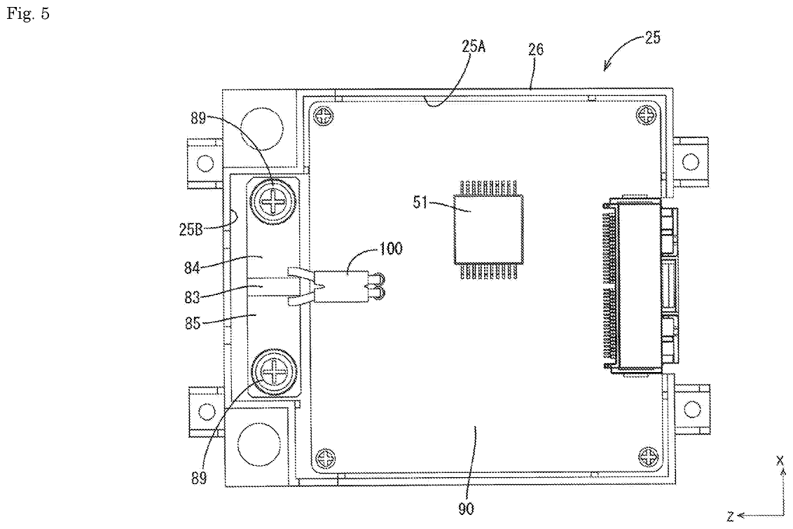

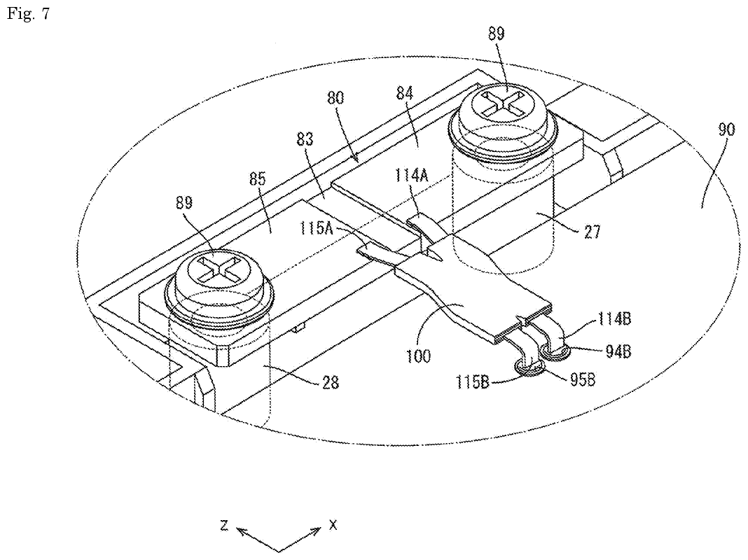

The automobile (an example of a vehicle) 1 includes the battery 20, which is an energy storage apparatus, as shown in FIG. 1. As shown in FIG. 2, the battery 20 includes a block-shaped battery case 21, and in the battery case 21, an assembled battery 30 including a plurality of secondary batteries 31, a resistor 80, a circuit board 90, and a flexible wiring board 100 (see FIGS. 5 and 7) are accommodated. In the following description, in a case of referring to FIG. 2 and FIG. 3, the vertical direction of the battery case 21 when the battery case 21 is placed horizontally without tilting with respect to the installation surface is referred to as the Y direction, the direction along the long side direction of the battery case 21 is referred to as the X direction, and the depth direction of the battery case 21 is referred to as the Z direction.

As shown in FIG. 3, the battery case 21 includes a box-shaped case main body 23 that opens upward, a positioning member 24 that positions the plurality of secondary batteries 31, an inner lid 25 that is mounted to an upper portion of the case main body 23, and an upper lid 29 that is mounted to an upper portion of the inner lid 25. In the case main body 23, a plurality of cell chambers 23A in which the secondary batteries 31 are individually accommodated are provided side by side in the X direction.

As shown in FIG. 3, a plurality of bus bars 24A are arranged on the upper surface of the positioning member 24, and the positioning member 24 is arranged above the plurality of secondary batteries 31 arranged in the case main body 23. Therefore, the plurality of secondary batteries 31 are positioned and connected in series by the plurality of bus bars 24A.

The inner lid 25 has a substantially rectangular shape in plan view as shown in FIG. 3, and a pair of terminal portions 22P and 22N to which harness terminals (not shown) are connected are provided at both ends in the X direction. The pair of terminal portions 22P and 22N are made of, for example, a metal such as a lead alloy. The terminal portion 22P is a positive electrode side terminal portion and the terminal portion 22N is a negative electrode side terminal portion.

As shown in FIG. 3, the resistor 80 and the circuit board 90 are arranged on the upper surface of the inner lid 25, and the inner lid 25 is closed by the upper lid 29 from above.

The electrical configuration of the battery 20 will be described with reference to FIG. 4. The battery 20 includes the assembled battery 30, the resistor 80, a current interruption device 45, a processing unit 51, a voltage detection unit 55, a memory 53, and a temperature sensor 57 that detects the temperature of the secondary battery 31. The processing unit 51, the voltage detection unit 55, and the memory 53 are mounted on the circuit board 90.

The assembled battery 30 includes the plurality of lithium ion secondary batteries 31 connected in series. The assembled battery 30, the resistor 80, and the current interruption device 45 are connected in series via an energization path 35. The resistor 80 is arranged on the negative electrode side, and the current interruption device 45 is arranged on the positive electrode side. The resistor 80 is connected to the negative electrode side terminal portion 22N, and the current interruption device 45 is connected to the positive electrode side terminal portion 22P.

The battery 20 is for starting an engine. As shown in FIG. 4, a starter motor 15 for starting an engine mounted in the automobile 1 is connected to the battery 20. The starter motor 15 is supplied with power from the battery 20 to be driven. The starter motor 15 is an example of the “engine starting device” in the present invention.

In addition to the starter motor 15, a vehicle load such as a vehicle ECU 16 and an alternator 17 are connected to the battery 20. When the power generation amount of the alternator 17 is larger than the power consumption of the vehicle load, the battery 20 is charged by the alternator 17. When the power generation amount of the alternator 17 is smaller than the power consumption of the vehicle load, the battery 20 is discharged to make up for the shortage.

The vehicle ECU 16 has a backup memory, which is a specific load that consumes power not only during running or stoppage but also during parking. As the specific load that consumes power during parking, in addition to the memory of the vehicle ECU 16, a security device of the vehicle 1 and a clock can be exemplified. The battery 20 discharges a large current of about 1000 A at the time of an engine start, and discharges a minute current of about several tens of mA during parking.

The current interruption device 45 is a semiconductor switch such as a relay or FET, and is arranged on the circuit board 90. The current interruption device 45 is arranged on the energization path 35 for the assembled battery 30 and opens and closes the energization path 35 for the lithium ion secondary batteries 31.

The voltage detection unit 55 is arranged on the circuit board 90. The voltage detection unit 55 detects the voltage of each lithium ion secondary battery 31 and the total voltage of the assembled battery 30.

The processing unit 51 is arranged on the circuit board 90. The processing unit 51 monitors the voltage of each lithium ion secondary battery 31 and the total voltage of the assembled battery 30 based on the power of the voltage detection unit 55. The current I of the lithium ion secondary batteries 31 is detected from the voltage Vr between both ends of the resistor 80, and the current I is monitored.

When the voltage, current, or temperature of the lithium ion secondary battery 31 is abnormal, the processing unit 51 sends a command to the current interruption device 45 to interrupt the current, thereby protecting the battery 20.

The processing unit 51 estimates SOC (state of charge) of the battery 20 based on the integral value of the current I obtained from the voltage Vr between both ends of the resistor 80 with respect to time, as shown in the following equation (2). The sign of the current is positive at the time of charging and negative at the discharging.

SOC=Cr/Co×100 (1)

Co is the full charge capacity of the secondary battery, and Cr is the residual capacity of the secondary battery.

SOC=SOCo+100×∫Idt/Co (2)

SOCo is the initial value of SOC, and I is the current.

The circuit board 90, the processing unit 51, the memory 53, the voltage detection unit 55, the resistor 80, and the flexible wiring board 100 constitute a management device 40 that manages the battery 20.

### 2. Connection Structure of Resistor 80 and Circuit Board 90

As shown in FIG. 3, a first accommodating portion 25A and a second accommodating portion 25B are provided on the upper surface of the inner lid 25. These two accommodating portions 25A and 25B are surrounded by an outer wall 26. As shown in FIG. 5, the circuit board 90 is accommodated in the first accommodating portion 25A in a state of being fixed by screwing. The circuit board 90 has a substantially rectangular shape, and electronic components such as the processing unit 51 are mounted on the upper surface of the board.

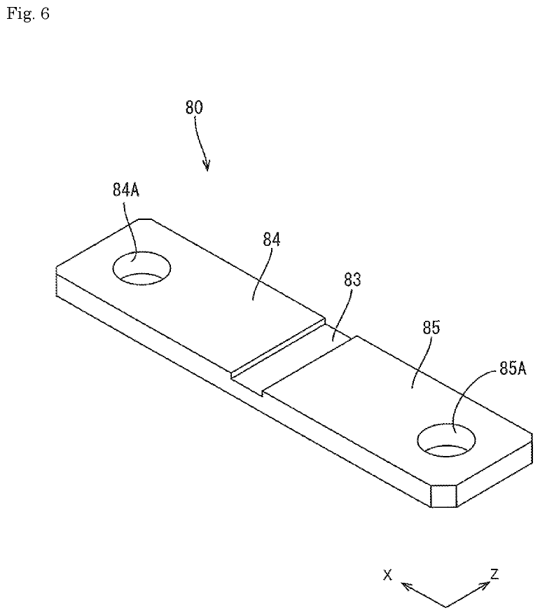

As shown in FIG. 6, the resistor 80 has a rectangular shape that is long in the X direction as a whole. The resistor 80 has a plate surface along the X-Z direction and is substantially parallel to the circuit board 90. The resistor 80 includes a resistor body 83 and a pair of plate portions 84 and 85. The resistor body 83 is made of manganin. The resistor body 83 produces a voltage proportional to the current.

The pair of plate portions 84 and 85 are made of copper. The pair of plate portions 84 and 85 are arranged on both sides of the resistor body 83 in the X direction. The pair of plate portions 84 and 85 have screw holes 84A and 85A.

The resistor 80 is mounted to the second accommodating portion 25B of the inner lid 25 by screwing the pair of plate portions 84 and 85 to bosses 27 and 28 with screws 89 together with a metal plate (not shown) that forms the conductive path 35.

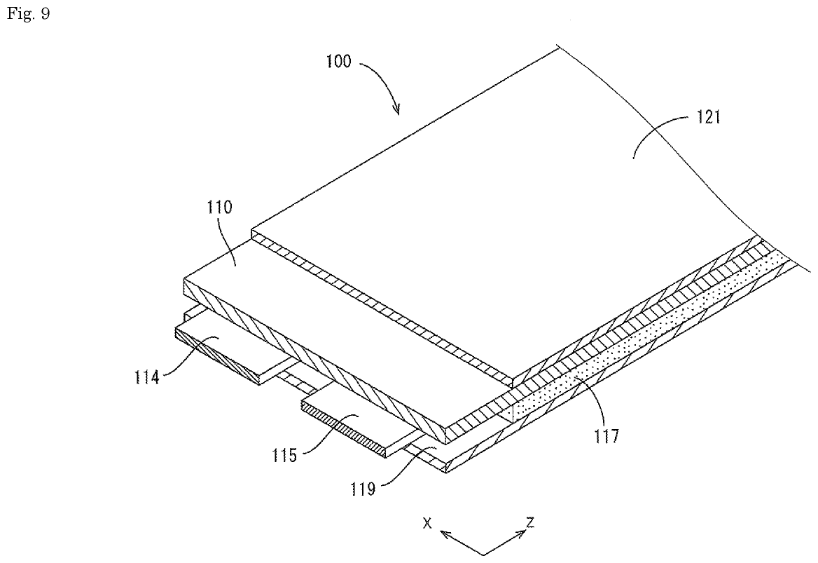

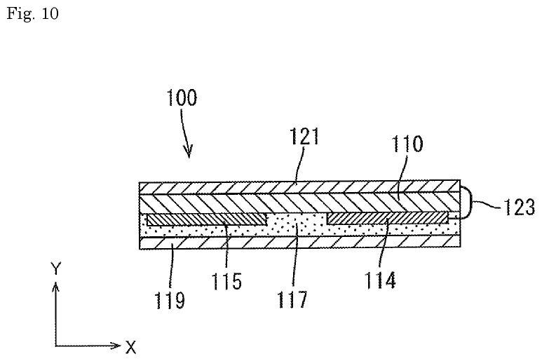

The flexible wiring board 100 is a connecting member that electrically connects the resistor 80 and the circuit board 90. The flexible wiring board 100 has a multi-layer structure, and as shown in FIGS. 9 and 10, includes a film substrate 110, two signal lines 114 and 115 forming a pair, an insulating layer 117, a cover film 119, and a shield layer 121. The film substrate 110 is a flexible insulating resin such as polyimide. The film substrate 110 has a thin elongated shape.

The signal lines 114 and 115 are conductive foils such as copper foils. The signal lines 114 and 115 are attached to the lower surface side of the film substrate 110 while being separated by a certain distance. The signal line 114 is a ground side signal line, and the signal line 115 is a plus side signal line. The signal lines 114 and 115 are examples of the “signal line” in the present invention.

The insulating layer 117 is arranged on the lower surface side of the film substrate 110. The insulating layer 117 covers the two signal lines 114 and 115 and insulates the two signal lines 114 and 115.

The cover film 119 is arranged on the lower surface of the insulating layer 117. The cover film 119 covers, from below, the two signal lines 114 and 115 attached to the lower surface of the film substrate 110.

The shield layer 121 is a metal foil and is attached to the upper surface side of the film substrate 110. The shield layer 121 is connected to the signal line 114 on the ground side by a wiring 123. The shield layer 121 extends over the entire upper surface of the film substrate 110, shields electromagnetic waves, and suppresses external noise from entering the signal lines 114 and 115.

The shield layer 121 only needs to cover at least the surfaces of the signal lines 114 and 115 that do not face the assembled battery 31, and in this example, covers only the upper surface sides of the signal lines 114 and 115. This is because the shield function of the assembled battery 30 makes it difficult for external noise to travel to the signal lines 114 and 115 from the surface sides that face the assembled battery 30 (lower surface sides).

Both ends of the signal lines 114 and 115 in the Z direction protrude from the film substrate 110, as shown in FIG. 7. One ends 114A and 115A of the signal lines 114 and 115 protruding from the film substrate 110 are welded and joined to both sides of the resistor body 83, respectively. Specifically, the one end 114A of the signal line 114 is welded to the plate portion 84 on one side of the resistor 80 in the vicinity of the resistor body 83, and the one end 115A of the signal line 115 is welded and joined to the plate portion 85 on the other side of the resistor 80 in the vicinity of the resistor body 83. The welding and joining is preferably laser welding or ultrasonic welding.

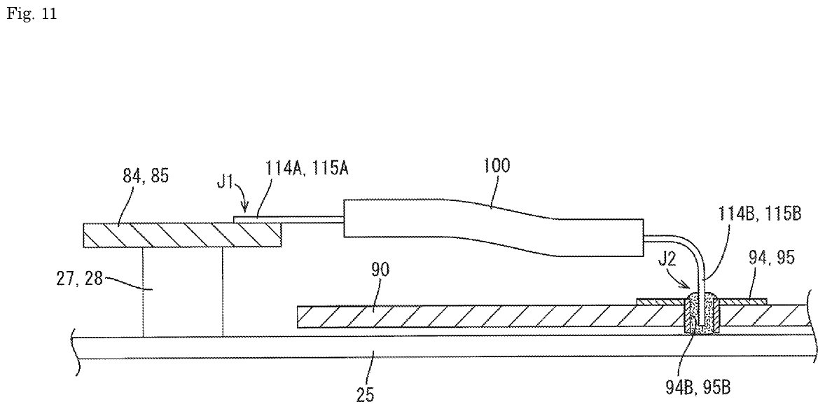

Other ends 114B and 115B of the signal lines 114 and 115 protruding from the film substrate 110 are welded and joined to the circuit board 90. Specifically, the circuit board 90 has a positive side conductive pattern 94 and a ground side conductive pattern 95. The circuit board 90 is provided with through holes 94B and 95B for electrically connecting the conductive patterns 94 and 95 and the signal lines 114 and 115, respectively. As shown in FIGS. 7 and 11, the signal lines 114 and 115 are welded and joined to the circuit board 90 by inserting the other ends 114B and 115B into the through holes 94B and 95B and soldering them.

The signal lines 114 and 115 of the flexible wiring board 100 electrically connect both the plate portions 84 and 85 of the resistor 80 and the conductive patterns 94 and 95 of the circuit board 90. As described above, since the processing unit 51 of the circuit board 90 is electrically connected to the resistor 80, the voltage Vr between both ends of the resistor 80 can be detected. Then, the current I of the secondary batteries 31 can be detected based on the detected voltage Vr between both ends, and SOC can be calculated.

### 3. Description of Effect

The battery 20 for starting the engine may be used in a medium SOC range where SOC is about 60% from the viewpoint of accepting regenerative energy. In order to reach full charge, charging from the medium SOC range is necessary, and it is necessary to secure the charging time. Securing the charging time is limited when the vehicle is in a long running state, etc., so that there is a problem that the opportunity to perform charging to full charge and correct the SOC estimation error (full charge correction) is limited. Therefore, it is required to increase the estimation accuracy of SOC by highly accurately measuring current from a minute current during parking to a large current at the time of an engine start.

As a method of connecting the resistor 80 and the circuit board 90, a method of connecting a terminal provided on the resistor 80 to a connector (not shown) of the circuit board 90 is conceivable. In the case of connection using the connector, a spring of the terminal provided on the connector deteriorates over time and becomes weak. Then, there is a concern that the contact of the terminal becomes unstable, which may increase the contact resistance. As another method, a method of connecting the resistor 80 and the circuit board 90 with an electric wire and screwing them together is conceivable. Also in the case of screwing, similarly to the connector, there is a concern that the contact resistance may increase due to loosening of the screw due to deterioration over time.

In this configuration, the signal lines 114 and 115 of the flexible wiring board 100 are welded and joined to the resistor 80 and the circuit board 90. In the welding and joining, the resistance of joining portions J1 and J2 is small, and the deterioration over time is small. Therefore, the current can be accurately measured in the battery 20 for starting the engine in which a large current flows.

Since the signal lines 114 and 115 have a function of an antenna, the current may be measured to be larger than the actual current value by detecting external noise such as electromagnetic waves due to static electricity or radio waves of a mobile phone. The measurement error caused by the external noise affects the measurement accuracy of the minute current. In this configuration, the shield layer provided in the flexible wiring board 100 shields external noise. Therefore, during parking, a minute current flowing from the battery 20 to the vehicle ECU 16 can be accurately measured.

In the present configuration, in the battery 20 for starting the engine in which the full charge correction is limited, by highly accurately measuring current from a minute current during parking to a large current at the time of an engine start, it is possible to increase the estimation accuracy of SOC.

The lithium ion secondary battery 31 has a smaller internal resistance than other secondary batteries such as a lead-acid battery. Therefore, a large current may flow at the time of an engine start, as compared with the lead-acid battery. When the resistor 80 is connected to the circuit board 90 using the connector, the contact of the terminal becomes unstable due to deterioration over time and the contact resistance increases. Therefore, at the time of an engine start at which a large current flows, the current measurement error increases, and the estimation accuracy of SOC tends to decrease. By applying the present technology, it is possible to maintain a low resistance state at the joining portion J1 between the one ends 114A and 115A of the signal lines 114 and 115 and the plate portions 84 and 85 of the resistor 80, and at the joining portion J2 between the other ends 114B 115B of the signal lines 114 and 115 and the through holes 94B and 95B of the circuit board 90 regardless of deterioration over time. Therefore, it is possible to solve the problem peculiar to the lithium ion secondary battery 31 that the measurement accuracy of the current tends to decrease at the time of an engine start at which a large current flows.

Soldering can be considered as a method of joining the signal lines 114 and 115. Soldering has the merit that the equipment is inexpensive and the manufacturing cost can be suppressed. However, at the time of an engine start, a large current flows, and the resistor 80 generates heat. Therefore, there is a concern that the joining portion J1 with the signal lines 114 and 115 may be affected such that the solder may start melting or the like. In this configuration, the one ends 114A and 115A of the signal lines 114 and 115 are joined to the resistor 80 by laser welding or ultrasonic welding. Since the melting point of copper, which is the base material of the signal lines 114 and 115, is higher than that of solder, even if a large current flows through the resistor 80 and heat is generated, the influence on the joining portion J1 with the resistor 80 is small and the reliability is high. Further, since the other ends 114B and 115B of the signal lines 114 and 115 are joined to the through holes 94B and 95B of the circuit board 90 by soldering, the manufacturing cost can be suppressed.

The flexible wiring board 100 has a lower heat conductivity than a covered electric wire in which a core wire (signal wire) is covered with an insulating layer, and the heat of the resistor 80 is hard to be transferred to the circuit board 90 side. Therefore, since it is possible to suppress thermal shock (rapid temperature change) to the joining portion J2 between the circuit board 90 and the signal lines 114 and 115, it is possible to suppress occurrence of solder cracks at the joining portion J2 with the circuit board 90. Further, since the flexible wiring board 100 is flexible, it is possible to reduce the concentration of stress on the joining portion J2 with the circuit board 90.

Since a large current flows at the time of an engine start and the lithium ion secondary battery 31 generates heat, in the case of the structure where the resistor 80 is accommodated in the same battery case 21 as the lithium ion secondary battery 31, heat is accumulated in the battery case 21, and the resistor 80 is likely to reach a high temperature. In this configuration, by using the flexible wiring board 100 having a low heat transfer rate, it is possible to suppress the transfer of heat from the resistor 80 to the circuit board 90, so that it is possible to suppress temperature rise of the joining portion J2 between the circuit board 90 and the flexible wiring board 100. Therefore, the structure is strong against heat.

### Other Embodiments

The present invention is not limited to the embodiment described above referring to the drawings, and, for example, the following embodiments are also included in the technical scope of the present invention.

(1) In a first embodiment, the lithium ion secondary battery 31 is illustrated as an example of the energy storage device. The energy storage device may be another secondary battery such as a lead-acid battery or a capacitor. The vehicle is not limited to the automobile 1 and may be a motorcycle.

(2) In the first embodiment, the management device 40 includes the circuit board 90, the processing unit 51, the memory 53, the voltage detection unit 55, the resistor 80, and the flexible wiring board 100. The management device 40 only needs to include at least the circuit board 90, the processing unit 51, the resistor 80, and the flexible wiring board 100, and the others are additional components.

(3) In the first embodiment, the flexible wiring board 100 is shown as an example of the connecting member. The connecting member only needs to be a configuration including a signal line and a shield layer that shields the signal line, and a shielded electric wire can be used in addition to the flexible wiring board 100. The shielded electric wire is an electric wire in which the periphery of the signal wire is covered with a shield layer.

(4) In the first embodiment, the one ends 114A and 115A of the signal lines 114 and 115 are joined to the plate portions 84 and 85 of the resistor 80 by laser welding or ultrasonic welding, and the other ends 114B and 115B of the signal lines 114 and 115 are soldered to the through holes 94B and 95B of the circuit board 90. The signal lines 114 and 115 only need to be connected to the mating member (the resistor 80 or the circuit board 90) by welding and joining. For example, both ends of the signal lines 114 and 115 may be joined to the resistor 80 and the circuit board 90 by soldering. Both ends of the signal lines 114 and 115 may be joined to the resistor 80 and the circuit board 90 by laser welding or ultrasonic welding.

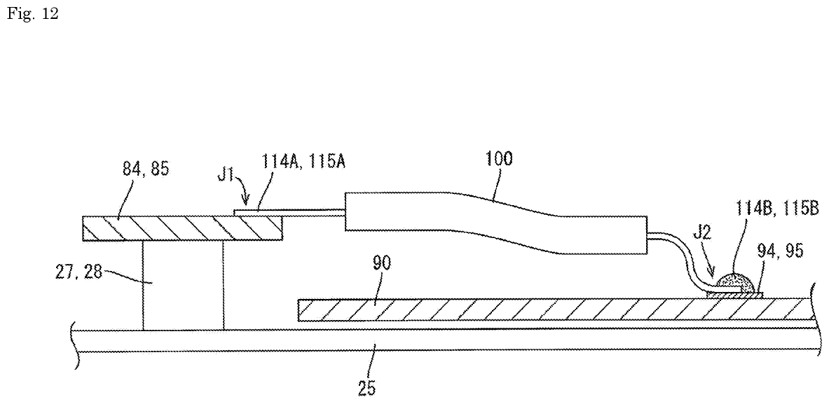

(5) In the first embodiment, the other ends 114B and 115B of the signal lines 114 and 115 are soldered to the through holes 94B and 95B of the circuit board 90. The soldering method is not limited to the method using the through holes. As shown in FIG. 12, the other ends 114B and 115B of the signal lines 114 and 115 may be overlapped and soldered on the conductive patterns 94 and 95 of the circuit board 90.

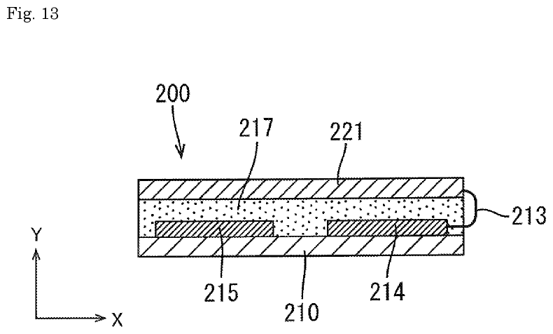

(6) In the first embodiment, as an example of the flexible wiring board 100, the structure including the film substrate, the two signal lines, the insulating layer 117, the cover film 119, and the shield layer 121 is shown. The flexible wiring board 100 only needs to be a configuration including at least a substrate, two signal lines, and a shield layer that shields the two signal lines, and is not limited to the configuration disclosed in the first embodiment. For example, as in a flexible wiring board 200 shown in FIG. 13, a structure in which signal lines 214 and 215 are arranged between a film substrate 210 and a shield layer 221 with an insulating layer 217 interposed therebetween may be employed. Reference numeral 213 is a wire that connects a signal line on the ground side and the shield layer 221.

### DESCRIPTION OF REFERENCE SIGNS

20: Battery
31: Secondary battery
40: Management device
51: Processing unit
80: Resistor
83: Resistor body
84A, 84B: Plate portion
90: Circuit board
100: Flexible wiring board (example of “connecting member” of present invention)
110: Film substrate
114, 115: Signal line (example of “signal line” of present invention)
117: Insulating layer
121: Shield layer

1. A management device for an energy storage device, the energy storage device being mounted in a vehicle and configured to supply power to a specific load that consumes power during parking, the management device comprising:
a circuit board equipped with a processing unit;
a resistor that detects a current of the energy storage device; and
a connecting member that electrically connects the resistor and the circuit board,
wherein the processing unit calculates SOC of the energy storage device based on the current detected by the resistor,
wherein the connecting member includes a signal line and a shield layer that shields the signal line,
wherein one end of the signal line is connected to the resistor by welding and joining, and
wherein the other end of the signal line is connected to the circuit board by welding and joining.

2. The management device according to claim 1, wherein the energy storage device comprises a lithium ion secondary battery.

3. The management device according to claim 1,
wherein the one end of the signal line is joined to the resistor by laser welding or ultrasonic welding, and
wherein the other end of the signal line is joined to the circuit board by soldering.

4. The management device according to claim 3, wherein the connecting member comprises a flexible wiring board including a substrate, the signal line, and the shield layer.

5. The management device according to claim 4, wherein the resistor is accommodated in a case that accommodates the energy storage device.

6. An energy storage apparatus comprising:
the management device according to claim 1;
an energy storage device; and
a case that accommodates the energy storage device and the management device.
